(19) United States
(12) Patent Application Publication
(10) Pub. No.: US 2008/0035492 A1
(43) Pub. Date: Feb. 14, 2008

(54) Oxygen Transport Structure

(76) Inventor: Donald Bennett Hilliard, El Granada, CA (US)

Correspondence Address: Donald Hilliard, P O Box 2169, El Granada, CA, 94018, US

(21) Appl. No.: 11/793,399

(22) PCT Filed: Dec. 19, 2005
(86) PCT No.: PCT/US05/46311

§ 371 Date: Jun. 18, 2007

Related U.S. Application Data
(60) Provisional application No. 60/636,985, filed on Dec. 17, 2004.

(51) Int. Cl. C25B 1/02; B01D 50/00; C25D 17/00; H01L 51/00

(52) U.S. Cl. 205/688; 204/242; 257/40; 257/E51.001

(57) ABSTRACT

An oxide-based electrolytic structure and process is disclosed, which is particularly useful for use as an oxygen separation device. The disclosed structures utilize thin film layers to provide the oxygen separation in conjunction with polymer substrate materials. The disclosed devices operate at relatively low temperatures to provide a relatively low flux density (typically 10⁻¹⁰-10⁻¹⁴ g/cm² sec) of ion conduction, compared to prior art solid oxide electrolytes, whereas substantial oxygen separation is provided over relatively large areas. The disclosed oxygen separation devices are particularly suited for protection of organic-based semiconductors.

### RELATED APPLICATIONS

The present application is related to U.S. Provisional Patent application Ser. No. 60/636,985 filed Dec. 17, 2004, of which it claims benefit.

### TECHNICAL FIELD

The invention relates generally to the fields of electrolytic oxide devices, and in particular, of thin film oxygen separation devices; and, more particularly, to such devices utilized with flexible substrates.

### BACKGROUND ART

Throughout this application, various publications and co-pending patent applications are referenced. In the present disclosure, each of these publications and applications in their entireties are hereby incorporated by reference.

The present disclosure relates to the use of metal-oxide (e.g., “solid oxide”) electrolytic assemblies in relatively low-temperature, flexible, thin-film devices. Solid oxide electrolytic research and development has hither-to been oriented toward the practical uses of such materials; namely, solid-oxide fuel cells, oxygen generation systems, and hydrogen generators utilizing dissociation of water. Examples of oxygen generation devices are taught in US patent Nos. U.S. Pat. No. 6,264,807, U.S. Pat. No. 5,582,710, U.S. Pat. No. 6,352,624, U.S. Pat. No. 6,194,335, U.S. Pat. No. 6,090,265, U.S. Pat. No. 5,972,182, and U.S. Pat. No. 5,332,483. Operating characteristics and design principles for solid oxide electrolytes and devices that utilize solid oxide electrolytes may be readily found in the relevant prior art. Overviews may be found in textbooks, such as High-temperature Solid Oxide Fuel Cells: Fundamentals, Design and Applications (S. C. Singhal, K. Kendall), Fuel Cell Technology Handbook (Gregor Hoogers, Editor), or Introduction to Ceramics (Kingery, Bowman, and D. R. Uhlmann)

These prior art solid-oxide devices typically utilize a catalyst to enable dissociation of a variety of oxygen-bearing molecules, such as diatomic oxygen, water, carbon dioxide, hydroxyls, etc. A large body of literature exists for describing the various compositions and mechanisms found effective in providing heterogeneous catalysis at the boundaries of such catalysts. Such catalysts typically comprise one or a number of transition metal oxides, noble metals, or refractory metals, depending on the desired characteristics.

For an application of solid-oxide electrolytes to be practical, oxygen conductivity in the electrolytic device must be substantial for the given application. In the listed past applications, the required oxygen diffusion rates through a utilized solid oxide membrane have accordingly been of such a magnitude as to require considerable heating to achieve the required flux of oxygen ions through the electrolytic membrane. The membrane materials used are commonly referred to as “fast ion conductors.” Of the fast oxygen conductors, yttrium-stabilized zirconia (YSZ) is perhaps the best-known and conventional example. In the last couple decades, various defective crystalline materials containing bismuth oxide, cerium oxide, gadolinium oxide have been favored to provide higher oxygen conductivity's at a given temperature (e.g., 600 C), though, such materials have frequently proven problematic, due in part to a lack of stability of these materials at high temperatures. Recently, various, more stable, alternative oxide chemistries have been explored with promising results. For example, a—less stable—bismuth oxide fluorite material may be surface-terminated with a more stable electrolyte, such YSZ. Also, more stable materials such as the barium-bismuth-iron-oxide compositions have shown promisingly high oxygen permeation.

The present disclosure also relates to environmental barriers. Encapsulation means for articles requiring protection from undesirable environmental constituents, including such constituents as water, oxygen, carbon dioxide, etc., have typically comprised material layers that are chosen to offer an excellent barrier to diffusion by the constituents. As such, these prior art encapsulation means are passive barrier structures that rely on the low diffusion constant attributable to the materials chosen, for diffusion by the constituent to be blocked. Since applications for these environmental barriers are typically those requiring either low-cost barriers or mechanical flexibility, such barriers are normally formed by one of various coating methods that allow for application of thin films of the barrier material. In food packaging, metallic films have been used with high success, due to their ductile nature, and low permeability. Transparent polymers have also found use for applications wherein their higher permeability, relative to desirable metals, is still adequate. However, many commercial applications for environmental barriers are arising that require barrier properties that are not satisfied by barrier solutions currently offered.

For example, many potential applications of organic-based semiconductors are currently being pursued, wherein a primary obstacle to commercial success exists in the inability to find an effective environmental barrier to oxygen and moisture, wherein the barrier provides transparency for light. There are also other applications wherein a more effective means to preclude oxygen-bearing molecules would be highly advantageous. Insofar as organic semiconductor devices are concerned, it is not only highly desirable to preclude oxygen-bearing molecules from impinging on a device to maintain functionality, but it is also very important that there not be a steady degradation or alteration of device performance as a result of oxygen contamination during the device's useful lifetime. The latter challenge is particularly difficult for these prior art barriers to address; that is, achieving steady-state device performance while experiencing an accumulating contamination level.

Barrier coatings frequently comprise multilayer coatings that incorporate inorganic layers. The inorganic layers are utilized for providing a permeation barrier to the unwanted environmental constituents, due to the low diffusion rate of such constituents in the typical inorganic materials (e.g., SiO₂) utilized. It has been found in the multilayer barriers of the prior art, that it is important for the layers of inorganic material to be separated by organic material to avoid crack and defect propagation in the inorganic material. This is because a crack, pinhole or other defect in an inorganic layer deposited by various methods tends to be carried into the next inorganic material layer when the next inorganic material layer is deposited directly onto the first layer of inorganic material with no intervening layer of organic material.

The multilayer barrier structures are most frequently deposited by vapor deposition. However, vapor deposition of inorganic materials onto organic substrates is restricted to relatively low-temperature processes, since the temperature of the substrate fixturing cannot exceed temperatures with which the organic substrate is compatible. As a result, many inorganic materials, particularly compounds, deposited onto organic substrates at the relatively low temperatures used are characterized by a low adatom mobility. This low adatom mobility can result in a porous film structure that exists at the nanoscale; typically, less than 100 nanometer voids, which produce essentially a “spongy” film when viewed with nanometer-scale resolution, even though the film may still appear quite specular when viewed at visible wavelengths of light. Clearly, such films are not compatible as permeation barriers, since such porous structures will readily allow high permeation rates for undesirable gases or vapors. Previous multilayer barrier structures have therefore striven to minimize pores, pinholes, and other such variously identified micron/sub-micron passageways that can frequently form in practical barrier films.

As is known in the art of vapor deposition, porous films of various inorganic materials, and in particular, inorganic compound materials, may be readily obtained by means of low temperature deposition of the inorganic material under various conditions. These porous film structures may vary considerably, but will typically comprise an open columnar microstructure, wherein the columns possess a relatively high material density, and the regions in between the columns comprise open pores or low-density porous material. However, various porous microstructures may be obtained as a function of the material deposited, substrate temperature, partial and total pressures, deposition method, type of energetic particle bombardment, etc. In sputter deposition, porosity of the deposited film can be easily varied, with the degree of porosity becoming increasingly large as sputtering pressure is increased, or as distance between sputter source and substrate is increased.

Difficulties in attaining dense, non-porous compounds—oxides, nitrides, fluorides, etc—materials in a thin film form are frequently addressed through the implementation of energetic deposition techniques. Such energetic deposition techniques utilize energetic particles—including ions, neutrals, photons, electrons, etc—to attain a structural morphology, in the deposited thin film, that is representative of an effective deposition temperature above that of the substrate. Accordingly, dense, polycrystalline (ceramic) films may be obtained on relatively low-temperature substrates.

Given the low modulus of elasticity provided by many of the inorganic barrier materials of interest in barrier applications, as well as the frequent existence of grain-boundaries, slip planes, and other such material defects in even the best inorganic barrier layers, propagation of fractures within such low-permeation inorganic layers can be expected as a result of relatively little environmental stress and cycling. Even if mechanical flexibility is not required, environmental cycling due to typical humidity and temperature cycling can be expected to have a cumulative effect on defect propagation and fracture so that the barrier properties of the inorganic layer will deteriorate over time. The reliability in sustaining such dense, fracture-free inorganic layers becomes increasingly unlikely, in the case that the multilayer barrier structure is to be subsequently subjected to mechanical stresses/strains as a result of bending, stretching, or compression.

### DISCLOSURE OF INVENTION

Electrolytic oxygen-ion conductors used in the present invention are preferably materials comprising “fast ion conductors” in the prior art, though such fast ion conductors are normally attributed their conductive characteristics at temperatures far above room temperature (600-1200° C.), wherein such materials are used in solid oxide fuel cells and in oxygen pumping (or generation) systems. Even recently favored solid oxide conductors utilizing bismuth oxide or barium-iron-oxide-type materials still require temperatures above 500° C. for use in the intended applications of solid oxide fuel cells and oxygen generation systems. However, in the present invention, such oxygen conductors are utilized in operating temperatures around room temperature, where the oxygen conductivity is accordingly several orders of magnitude less than that normally found useful.

In the first preferred embodiments, such electrolytic materials provide useful oxygen conductivity at room temperature as a result of being used in an oxygen transporting device that requires only a very small oxygen flux density for effective application.

Oxide electrolytes such as the solid oxide electrolytes of the present invention provide oxygen conductivity in fairly good agreement with the Nernst-Einstein equation. Accordingly, diffusion coefficients for oxygen in such electrolytes are found to be roughly linear on an Arrhenius scale, and the magnitude of the conductivity or diffusion coefficient of oxygen at room temperature and below is therefore non-vanishing. Such room-temperature oxygen conductivity is normally of little use in real-world applications. Yet, the present invention utilizes such low oxygen conductivity in an oxygen pumping device that is preferably used to off-set only a very small leakage of oxygen, namely, the leakage (or diffusion) of oxygen-bearing molecules that permeate multilayer environmental barriers to contaminate an oxygen-sensitive article

As such, oxygen conduction through a suitable active barrier electrolyte of the present invention may be less than 10⁻¹⁴ g/cm²sec, while still providing substantial improvement in barrier properties. Oxygen conductivity in the presently disclosed electrolytic assemblies is preferably in the range of 10⁻¹⁰-10⁻¹⁴ g/cm²sec, although oxygen conduction well outside of this range may be realized without departing from the scope of the invention.

In its first preferred embodiment, the disclosed electrolytic device comprises a thin film multilayer structure that includes a cathode layer for providing electronic current, an opposing anode layer for collecting electronic current, and an electrolytic layer disposed between cathode layer and anode layer for transporting oxygen ions therebetween, thereby providing a continuous electrical current path, the layers disposed for transporting oxygen from a volume for which oxygen depletion is desirable. A catalytic material is preferably disposed between the cathode layer and electrolytic material for providing efficient dissociation of oxygen-containing molecules. The first embodiment comprises an electrolytic assembly that may be economically formed over large areas (m²), particularly for applications wherein a low operating temperature (<100° C.) and low oxygen pumping density (typically <10⁻¹⁰ gram/cm² second) is desirable. The electrolytic material preferably comprises an inorganic oxide electrolyte, preferably a bismuth-oxide-based “fast ion conductor”, so that the inorganic electrolyte layer simultaneously provides an effective barrier material against undesirable diffusion of oxygen-containing molecules in a direction opposite that of the intended ion flow. The electrolytic assembly of the present invention is particularly suited for use as an environmental barrier for the encapsulation and protection of oxygen-sensitive/moisture-sensitive electronic components formed on or in flexible substrates (e.g., PET), and in particular, electronic components comprising organic light-emitting devices.

In a second embodiment, a multitude of the disclosed thin-film electrolytic assemblies are formed into a larger multilayer stack of electrolytic assemblies, so that greater resistance to non-electrolytic gas diffusion may be achieved in the same structure, while still providing mechanical flexibility. An electrolytic stack of this second embodiment is disposed on either side of a relatively thin (<1 mm) flexible material comprising the protected article—such as PET polymer film or organic semiconductor—that contains an oxygen-sensitive component.

In a third embodiment, the multilayer electrolytic stack is disposed on one side of the thin flexible material, and a passive barrier is disposed on the opposite side of the flexible material. The passive barrier may comprise a transparent polymer-oxide multilayer used in prior art environmental barriers, or it may comprise other barrier structures such as metal layers, etc. The electrolytic stack may be utilized to provide oxygen pumping from the flexible material so as to enable an oxygen density within the flexible material that is below an acceptable maximum. In this way, the disclosed electrolytic stack may be utilized to offset oxygen contamination of the flexible material due to leakage by the passive barrier. In the case that the passive barrier provides good barrier properties, but is opaque, the electrolytic stack may comprise transparent materials for transmitting optical radiation from an organic light emitting diode disposed on or in the flexible material.

In a fourth embodiment, the electrolytic layer of the electrolytic assembly is a heterogeneous layer that incorporates organic and inorganic material phases, so that there is enabled greater flexibility in the electrolytic assembly. The heterogeneous electrolytic layer may possess an isotropic phase separation, or it may be layered, graded, columnar, or otherwise anisotropic in its composition.

In preferred embodiments of the disclosed barrier, a function of the barrier is to prevent environmental constituents including but not limited to water, oxygen and combinations thereof from reaching the protected article. Accordingly, the invention is a structure and method for preventing water or oxygen from a source thereof reaching an electronic device. Due to the novel properties of the disclosed electrolytic barrier—in particular, the characteristics of both an effective permeation barrier combined with those of a relatively flexible material—it may be found advantageous to substitute the disclosed electrolytic assembly for either the organic or inorganic layers used for barrier properties in prior art organic-light-emitting-diode structures. Alternatively, the electrolytic barrier of the present disclosure may be interleaved with the existing barrier materials of the prior art organic-light-emitting-diode devices. There are numerous such devices that incorporate a barrier structure in the prior art, many of which teach barrier multilayers comprising distinct layers of transparent inorganic materials alternating with distinct layers of transparent polymers. Such organic-light-emitting-diode devices are disclosed in numerous references, including US patents U.S. Pat. No. 6,503,634, U.S. Pat. No. 6,503,634, U.S. Pat. No. 5,686,360, U.S. Pat. No. 5,757,126, U.S. Pat. No. 5,757,126, U.S. Pat. No. 6,413,645, U.S. Pat. No. 6,413,645, U.S. Pat. No. 6,497,598, U.S. Pat. No. 6,497,598, and various referenced and referencing patents of these disclosures, as well as the following US patent applications: US200030124392, US200030124392.

The disclosed invention utilizes inorganic solid oxide electrolytes in its first preferred embodiment, and preferably stabilized Bi₂O₃-containing solid oxides such as yttria-stabilized bismuth-oxide (YSB). Alternatively, other well-known oxide electrolytes, such as stabilized cerium oxides and zirconium oxides may also provide sufficient properties. Other preferred electrolytes include substituted barium-iron-oxide-type compounds. These latter compositions include the barium-bismuth-cobalt-iron-oxide BaBiₓCo_{y}Fe_{0.8-y}O_{z} (BBCFO) compounds. Also having useful properties in the present context is strontium-cobalt-iron-oxide (e.g., SrCo_{0.8}Fe_{0.2}O₃) compounds, strontium-bismuth-cobalt-iron-oxide, yttrium-bismuth-copper-oxide compounds, erbium-bismuth-oxide, lanthanum gallates, and others. As in previous solid oxide electrolytes, various anions, such as fluorine or nitrogen, may also be used to provide additional properties in the oxygen conductors of the present invention.

In another preferred embodiment, the electrolytic layer is a heterogeneous material with a nano-scale phase structure. In such a heterogeneous electrolyte, the electrolytic layer may comprise one or several materials that provide substantial oxygen conductivity. The heterogeneous material may include organic materials, inorganic materials, or a combination of organic and inorganic materials.

Accordingly, polymer electrolytes may be alternatively used, wherein such oxygen-containing compounds as organopolysiloxanes, organopolysilanes, and various silicones may provide sufficient oxygen conductivity alone or in a composite or solid solution with other materials. These various electrolytes may be used as homogenous layers, or alternatively, in composite layers wherein the electrolyte is present in combination with another material in a heterogeneous layer.

The electrolytic materials of the present invention may be utilized in conjunction with a catalytic layer that enables dissociation of oxygen-containing molecules such as water and carbon dioxide. While the catalytic material is preferably formed as a heterogeneous layer for providing optimal three-phase interaction, the low level of oxygen pumping required does not necessarily require a heterogeneous structure. Catalytic materials for use in the present invention may include any of those found effective in the prior art of electrolysis, though the catalyst is preferably optically transmitting in the first preferred embodiment. Accordingly, the catalytic material may include various forms of cerium oxide, iridium oxide, indium-tin oxide compounds, platinum, RuO, etc. In the case that the disclosed electrolytic barrier is utilized on only one side of an optically emitting device, such as on the back-side of an organic light-emitting display, non-transparent materials may be used.

Electrode layers of the present invention are utilized to form the electrical circuit of the disclosed electrolytic system, providing electrical current and electric fields in a manner similar to electrolytic oxygen generation systems (OGS') of the prior art. The electrode layers are transparent conductors, such as indium-tin oxide (ITO), in the first preferred embodiment, so that the disclosed electrolytic barrier structure may be utilized in conjunction with flexible electronics and displays.

The materials utilized for the barrier of the present invention are optically transmissive in the first preferred embodiment, so that the barrier may be utilized for organic light-emitting devices. However, the materials may be either optically transparent or opaque, as may be optimal for given application.

It is to be understood that any number of additional layers may be incorporated in combination with the disclosed electrolytic structures, including but not limited to additional barrier layers, dessicant layers, temperature controlling layers, resistive heaters, peltier junctions, device layers, etc. Other objects and advantages are as follows:

One object of the invention is to provide a multilayer barrier structure that may be economically fabricated on a commercial scale.

Yet, another object of the invention is to provide an oxygen-transporting electrolytic assembly that possesses desired properties of both glass and polymer layers.

Another object of the invention is to provide an electrolytic device that provides useful oxygen pumping at temperatures less than 200 C.

Another object of the invention is to provide an electrolytic device that enables the use of polymer-inorganic composite layers as an electrolytic medium.

Another object of the invention is to provide an electrolytic device that impedes oxygen diffusion in a direction opposite of the direction of oxygen ion pumping.

Another object of the invention is to provide an electrolytic device that comprises a barrier for protecting flexible electronics.

Another object of the invention is to provide an moisture barrier that removes moisture and other oxygen-bearing molecules from an organic-light-emitting-diode device.

Another object of the invention is to provide an electrolytic device that comprises a flexible oxygen pump.

Another object of the invention is to provide an electrolytic device that utilizes very low current densities <10 mA/m².

Another object of the invention is to provide a multilayer barrier structure that incorporates an oxygen-transporting electrolyte.

Another object of the invention is to provide a multilayer barrier structure that incorporates a plurality of oxygen-transporting electrolytic layers.

Another object of the invention is to provide a multilayer barrier structure wherein an oxygen-transporting electrolytic assembly is incorporated, wherein an electrolytic layer possesses a graded composition.

Another object of the invention is to provide a process and method for producing a multilayer barrier structure, wherein a monomer permeates a highly defective inorganic layer to produce a composite electrolytic layer.

Another object of the invention is to provide a process and method for producing a multilayer barrier structure, wherein inorganic/organic composite layers are formed in a highly reproducible vapor deposition process.

Another object of the invention is to provide a process and method for producing a multilayer barrier structure, wherein a highly defective inorganic layer is impregnated with monomer through a high degree of surface activation.

Another object of the invention is to provide a process and method for producing a multilayer electrolytic assembly, wherein a highly defective inorganic layer is impregnated with monomer so that a heterogeneous organic/inorganic composite structure is produced, wherein the composite structure possesses feature sizes of several to hundreds angstroms.

The subject matter of the present invention is particularly pointed out and distinctly claimed in the concluding portion of this specification. However, both the organization and method of operation, together with further advantages and objects thereof, may best be understood by reference to the following description taken in connection with accompanying drawings wherein like reference characters refer to like elements.

### BRIEF DESCRIPTION OF DRAWINGS

FIG. 1 is a sectional side-view of an electrolytic assembly of the invention.

FIG. 2 is a sectional side-view of an electrolytic barrier of the invention, utilized in a flexible electronic device.

FIG. 3 is a sectional side-view of an alternative embodiment of the invention.

FIG. 4 is a sectional side-view of another alternative embodiment of the invention, utilizing a composite electrolytic layer.

FIG. 5 is a sectional side-view of a preferred application of the invention for hermetically sealing an organic light-emitting device.

### DESCRIPTION OF THE PREFERRED EMBODIMENTS

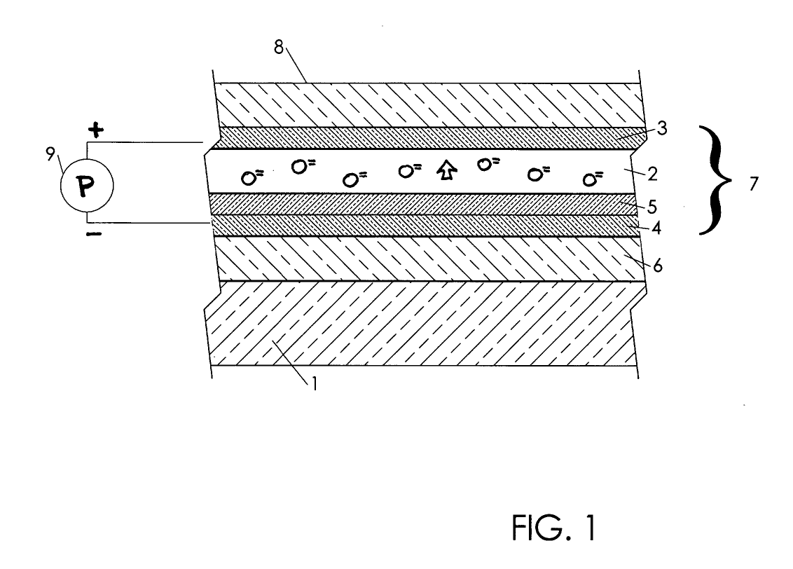

The following description and FIGS. 1-5 of the drawings depict various embodiments of the present invention. The embodiments set forth herein are provided to convey the scope of the invention to those skilled in the art. While the invention will be described in conjunction with the preferred embodiments, various alternative embodiments to the structures and methods illustrated herein may be employed without departing from the principles of the invention described herein.

FIG. 1 is a sectional side-view of an electrolytic assembly of the invention. The protected article (1) preferably comprises a material that is substantially permeable to oxygen or moisture, the protected article may comprise a substrate including a component that is sensitive to oxygen or moisture, so that preventing oxygen transport to the protected article is desirable. Accordingly, such oxygen-sensitive components may comprise various types of organic light-emitting materials, thin-film transistor (TFT) based organic semiconductor devices, organic photovoltaics and detectors, organic switches, Li-based battery-related structures, etc.

In its first embodiment, the invention utilizes a electrolytic layer (2), which is preferably composed of an inorganic oxide, in particular, compounds selected from compositions of barium-bismuth-cobalt-iron-oxide or yttrium-stabilized-bismuth-oxide. Though, the electrolytic layer may be organic, inorganic, or a composite material comprising both organic and inorganic phases. The electrolytic layers of the present embodiment are preferably quite thin (<200 nm), thereby providing flexibility as well as an accordingly higher electric field within the electrolyte for a given applied voltage between the electrodes.

The anode layer (3) is preferably an electrically conductive material that is optically transmitting, such as a transparent conducting oxide; for example, indium-tin oxide (ITO). The electrodes may alternatively be an electrically conductive polymer, or in some cases, a porous inorganic layer that contains either open or polymer-filled pores. The cathode layer (4) may be constructed similarly to the anode layer; also, the cathode layer may incorporate materials, such as cerium oxide, platinum, Iridium oxide, or other materials known for dissociative catalysis, so that oxygen may be separated from various oxygen-bearing molecules.

In the case that the cathode layer (4) does not provide adequate catalytic action, the cathode layer is preferably formed with an adjacent catalytic layer (5) between the cathode layer and electrolytic layer for increasing efficient dissociation of oxygen molecules and incorporation of oxygen ions into the electrolyte. Alternatively, the cathode may provide sufficiently efficient electrolytic action without a separate catalytic layer. The catalytic layer may also be vanishingly thin (>10 nm) while still substantially improving catalytic performance. The dual-layer cathode/catalyst of FIG. 1 is preferred for utilizing a relatively low-resistance current carrier for the cathode material (e.g., ITO), whereas the catalytic layer may be of relatively high resistivity; for example, common catalytic materials based on NiO, IrO, RuO₂, CrO₃, vanadium oxides, various defective perovskites (including the various lanthanum, manganese, chromium oxides of prior art fuel cells), cerium oxide, etc.

An intermediate polymer layer (6) is preferably utilized to provide a continuous insulating layer over the protected article for formation of the electrolytic assembly thereon. An individual electrolytic assembly (7) comprises material layers forming the active electrolytic device structure—namely, the anode layer (3), electrolytic layer (2), cathode layer (4), and optional separate catalytic layer (5), thereby providing a continuous current path between cathode layer and anode layer.

A top insulating layer (8) is preferably formed over the other-wise exposed surface of the electrolytic assembly for purposes of providing electrical isolation and durability. The top insulating layer may comprise any variety of insulating materials, including a flexible polymer film (e.g., Mylar®), additional environmental barriers, etc.

A power source (9) provides electrical power for driving oxygen ions through the electrolytic layer from the cathode layer to the anode layer. Of course, precise voltage drop across the electrolyte, as well as current densities, will be determined by the highly variable conditions to which the electrolytic assembly might be subjected. Optimally, the electrolyte is required to pump a minimal amount of oxygen (e.g., <10⁻¹²g/cm²sec), due to incorporation of effective passive barrier properties in the electrolytic assembly; namely, the ability of the inorganic layer to prevent oxygen-bearing molecules from diffusing in a direction opposite that of the intended ionic current. Accordingly, the current density in the electrolyte can be well below its oxygen pumping capacity. The electrolytic materials of the present invention may also provide a finite electron conductivity, as well, without appreciable diminishing the utility of the electrolytic properties; in fact, such electron current may be found useful in certain circumstances, such as when a certain degree of resistive heating of the electrolyte is desirable.

Because of the thin aspect of the preferred electrolytic layers (<200 nm), it is also be provided that very small impressed voltages are required for obtaining desired electrolytic action from the electrolytic assembly, preferably less than 5 Volts, and typically less than 1 Volt. It may further be seen that, when utilized over large areas typical of luminescent displays, the electrolytic assemblies of the present invention can provide a substantial capacitance. Such capacitance may be utilized as an energy storage means that is utilized for powering the display device, such energy storage being particularly useful for un-interruptable power.

The power source (9) preferably provides means for monitoring electrical characteristics of the electrolytic assembly, so that changes or degradation of the electrolytic assembly may be monitored. Through monitoring of such observable electrical characteristics as electronic current, DC resistance, AC impedance, etc., information may be obtained concerning a state or expected lifetime of the oxygen barrier or protected device. In addition, when several electrolytic assemblies (7) are operated in series, power may be preferentially provided to one assembly over another, so as to optimize barrier or device lifetime.

Of course, in FIGS. 1-5, sectional side-views are increased in scale for purposes of disclosure. Accordingly, the lateral dimensions parallel to layers will typically be orders of magnitude greater than the thickness' of the various embodied structures. For example, the preferred thickness of most electrolytic assemblies of the present invention will be on the order of tenths of microns (e.g., 0.5 μm); whereas, lateral dimensions of the device may be on the order of meters².

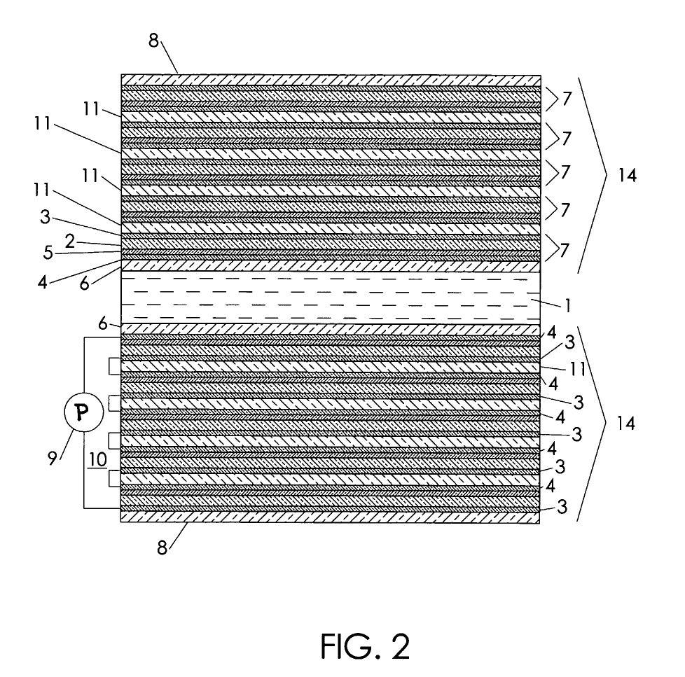

FIG. 2 is a sectional side-view of an electrolytic barrier of the invention, once again utilized for protection of a protected article (1), which is preferably a material structure that comprises or includes an oxygen or moisture-sensitive component, such as an organic light-emitting diode of a flexible electronic device. Such oxygen-sensitive or moisture-sensitive components might also comprise any other material item, including but not limited to various organic electronic materials, biological samples or specimens, foodstuffs, etc.

The electrolytic barrier of FIG. 2 comprises an electrolytic stack (14), which is a multilayered structure formed from a plurality of electrolytic assemblies (7), wherein the individual electrolytic assemblies may be powered individually, or coupled in series or parallel to a single power source.

The separation layers (11) are preferably a polymeric material utilized between each electrolytic assembly so as to provide flexibility when the electrolyte is an inorganic material.

The electrical circuit (10) of FIG. 2 is an alternative embodiment to the previous use of an isolated circuit devoted to each separate electrolytic assembly (7), in that the multitude of electrolytic assemblies are connected in series to a single power source (9). Of course, various electronic circuits previously disclosed for control and monitoring of current and voltage to electrolytic assemblies may be utilized.

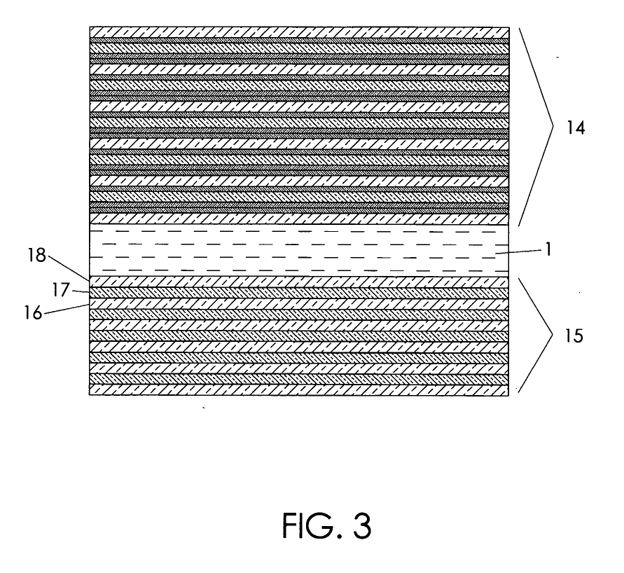

FIG. 3 is a sectional side-view of an alternative embodiment of the invention, wherein the electrolytic stack (14) is formed on a first side of a thin flexible material including an oxygen-sensitive component. A passive environmental barrier is formed on a second side opposite the electrolytic stack.

The passive barrier (15) may be a polymer-oxide multilayer, as is commonly taught in the art of flexible moisture/oxygen barriers. The term “passive barrier” in the present context shall refer to those environmental barriers that do not utilized a power source for pumping unwanted elements away from the protect component, such as the polymer-oxide multilayers and metallized multilayers of the prior art.

Polymer-oxide barriers of the prior art typically use many layer pairs of polymer and inorganic oxide layers. The polymer layer (16) is comprised typically of acrylates or other cured polymer materials disclosed in the prior art for thin film polymers. The inorganic layer (17) is comprised typically of such oxides as silica, titania, alumina, etc. A first polymer layer (18) is typically utilized for smoothing and structural purposes.

It should be noted that electrolytic layer (2), anode layer (3), and cathode layer (4), need not be transmissive when the embodiments of FIG. 3 are utilized in conjunction with an organic light emitting material, such as when the protected article (1) is an organic-light-emitting-diode device, since only the passive barrier (15) need be optically transmissive for viewing of emitted light. In the embodiments of FIG. 3, the passive barrier (15) may suffer from slow diffusion of oxidizing species, whereas the oxygen-sensitive material in the protected article (1) can be prevented from degradation by the oxygen pumping action of the electrolytic stack (14), which maintains oxygen levels within the substrate below a damaging level.

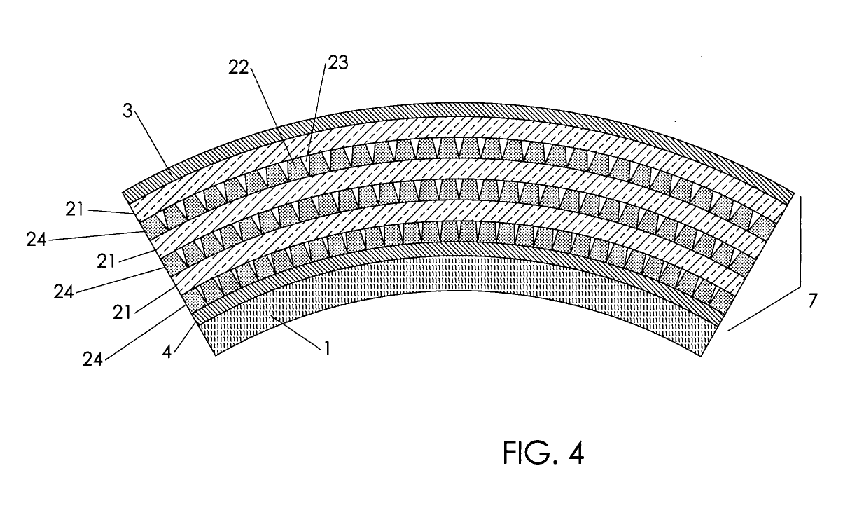

FIG. 4 is a sectional side-view of another alternative embodiment of the invention, utilizing a composite electrolytic layer, which is a superstructure formed from the layers residing between the anode (3) layer and cathode layer (4).

Heterogeneous layers (24) of the composite electrolytic layer, in FIG. 4, are formed by a composite material that contains at least an inorganic phase (22) and an organic phase (23), so that the heterogeneous layers may possess greater flexibility than that of solid inorganic layers, while still providing a desired barrier to oxygen-containing molecules that would otherwise travel towards the protected article (1). In addition, the heterogeneous layer of FIG. 4 is preferably an electrolyte that provides improved electrolytic properties as a result of possessing a large internal surface area. The inorganic phase (22) is preferably an oxide electrolyte, whereas the organic phase (23) is preferably a polymeric material that provides the composite electrolytic layer of FIG. 4 increased mechanical flexibility.

However, the heterogeneous electrolytic layers may possess electrolytic properties due to its inorganic phase, organic phase, or both phases providing ion conduction. The heterogeneous layers may contain inhomogeneities that exist on a nanometer scale or greater.

The inter-electrolyte layers (21) of FIG. 4 are preferably ionically or electronically conducting, so that the multitude of layers between the cathode layer and anode layer, in FIG. 4, provide a continuous current path between the cathode layer and anode layer, thereby providing the single electrolytic assembly (7).

Inter-electrolyte layers (21) are preferably an electrically conductive polymer such as polypyrole, polyanilene, PDOT, etc. Alternatively, the inter-electrolyte layers may also comprise a polymer material that is ionically conductive. It is to be understood that the very small current densities of the disclosed electrolytic assembly are sufficiently small that a large variety of materials may provide the required conductivity; such conductivity may be provided by a variety of doped materials, solid solutions, semiconductors, etc.

The anode layer and cathode layer of FIG. 4 may also comprise non-conventional conductive materials that provide less conductivity than commonly used conductive oxides and conducting polymers. Accordingly, these electrode layers may comprise heterogeneous materials as well.

In one possible embodiment, the electrolytic layer comprises a composite mixture of an inorganic electrolytic oxide and an organic oxide polymer, such as organopolysiloxanes, organopolysilanes, various silicones and the like.

In an alternative embodiment, the heterogeneous layer of FIG. 4 may be formed of electrically conductive, non-electrolytic compositions, and the inter-electrolyte layers (21) may provide the required electrolytic properties.

Heterogeneous layers of organic and inorganic phases may be formed by various means described in the prior art, or by means disclosed in co-pending U.S. patent application Ser. No. 10/934530 of same author. Apparatus for curing of a monomer to form the polymer material may accordingly be performed by plasma curing, high-voltage electron-beam curing, or UV curing; alternatively, such curing may be performed by a relatively low-voltage means of electron-assisted deposition, as disclosed in co-pending U.S. patent application Ser. No. 10/375,938 by same author.

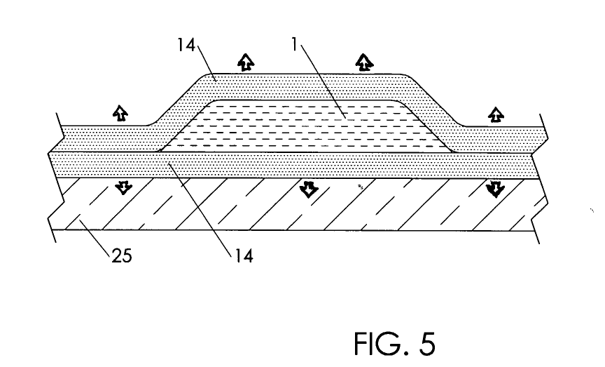

FIG. 5 is a sectional side-view of the invention utilized for hermetically sealing an organic light-emitting device. The protected article (1) is thus preferably an organic light-emitting device, which is preferably formed over the bottom electrolytic stack. The previously described layers of the electrolytic stacks (14) are, of course, conformal to the protected article, so that oxygen conduction within the electrolytic layers of the electrolytic stacks is orthogonal to the layers, as indicated by the arrows of FIG. 5.

Often, it is desirable to build devices onto a pre-existing flexible substrate that supports the encapsulated device, wherein such a flexible substrate (25) is typically a flexible polymer of use in the field of flexible electronics, such as PET. The flexible substrate may consist of any of a number of polymer films utilized in previous web coating applications, such as PET, PMMA, polyimides, polyamides, aramids, polypropylene, polysulfones, polynorborenes, Kaptons, polypyroles, polyanilenes, or any other flexible substrate material.

Alternatively, the electrolytic stacks (14) may be, at some previous stage, a free-standing assembly that is formed through release from a initial substrate material utilized for formation of the electrolytic assembly, so that the structure of FIG. 5 may be formed without any additional substrate material other than the protected article (1) to which the electrolytic assemblies are attached.

Inorganic electrolytic materials utilized in the various embodiments of the present invention may comprise amorphous or crystalline phases. In the case that the inorganic material is crystalline, energetic deposition processes may be utilized to provide non-equilibrium formation of the crystalline phase over organic substrates, so that the organic substrate does not experience the elevated temperatures associated with equilibrium phase-formation of the crystalline material.

Furthermore, it may be found that the electrolytic pumping of oxygen is due to either predominantly solid state diffusion through the electroyte, or, in some cases, diffusion of oxygen along internal surfaces of a given heterogeneous electrolytic layer. For example, it is feasible that oxygen ions that are chemisorbed onto internal surfaces of a nanostructured bismuth oxide layer may also react to an electrical field or chemical potential of the disclosed electrolytic device, wherein activation energies required for providing diffusion of the oxygen ions along such a surface may be considerably lower than that required for enabling diffusion of oxygen within the bulk of a crystalline or amorphous phase of the electrolytic layer. Accordingly, various such mechanisms may contribute to the pumping of oxygen through the electrolytic layer. However, all such mechanisms that enable transport of an oxygen-containing ions through the nominally electrolytic layer by means of an applied electric field between the electrodes will herein be referred to as “electrolytic”.

In addition to uncoated substrate materials or semiconductor devices, the substrates of the present invention may be any underlying material of prior art barrier structures, including but not limited to the various polymer, glasses, ceramics, polycerams, composites, etc, as well as any additional thin film structure taught in the prior art of barrier structures and devices combined therewith.

Formation of the disclosed electrolytic structures may be accomplished by a variety of means; however, in the preferred embodiments of the present invention, the disclosed electrolytic structures is formed by vacuum vapor deposition methods and apparatus readily available in prior art manufacturing processes. Accordingly, the disclosed electrolytic structures of the present invention may be formed utilizing a variety of prior art vapor sources. The inorganic vapor source may comprise any appropriate source of the prior art, including but not limited to sputtering, evaporation, electron-beam evaporation, chemical vapor deposition (CVD), plasma-assisted CVD, etc. Monomer vapor sources may similarly be any monomer vapor source of the prior art, including but not limited to flash evaporation, boat evaporation, Vacuum Monomer Technique (VMT), polymer multilayer (PML) techniques, evaporation from a permeable membrane, or any other source found effective for producing a monomer vapor. For example, a monomer vapor may be created from various permeable metal frits, as previously in the art of monomer deposition. Such methods are taught in US patents U.S. Pat. No. 5,536,323 (Kirlin) and U.S. Pat. No. 5,711,816 (Kirlin), amongst others.

Vacuum deposition means for the inorganic materials may be any method used for vacuum deposition, including but not limited to chemical vapor deposition, plasma enhanced chemical vapor deposition, sputtering, electron beam evaporation, electron cyclotron resonance source-plasma enhanced chemical vapor deposition (ECR-PECVD) and combinations thereof. Deposition of the inorganic porous structures may also be accomplished by such non-vacuum techniques as LPE, Sol-Gel, MOD, electrophoretic dep., etc.

### INDUSTRIAL APPLICABILITY

The invention finds application in a variety of applications, and in particular, environmental barrier applications; in particular, the invention is suitable for providing encapsulation in flat-panel displays, including those required for organic-light-emitting-diode and LCD related devices. For example, the novel barrier structures disclosed herein may be used to replace either organic or inorganic layers utilized in any of the various multilayer barrier structures of the prior art, thereby providing the advantages of the disclosed invention. The invention is accordingly seen as particularly suitable for providing barrier properties in flexible electronics, particularly in flexible displays.

It should be recognized that the disclosed electrolytic assembly may alternatively be utilized for other applications requiring oxygen ion pumping, such as in the generation of pure oxygen at relatively low temperatures. Alternatively, the disclosed electrolytic structures may find application for generation of electrical power through oxidation of hydrogen-bearing molecules. The disclosed oxygen transport structures are not intended to be limited to a specific range of oxygen permeation or conductivity. Because oxygen pumping speed will increase in an exponential fashion as device temperatures rise, the inventive structures of the present invention can be usefully applied at a wide range of temperatures; namely, within the temperature range in which the incorporated polymeric materials are compatible, which is typically below 250 Celcius. For example, a Kapton substrate may enable a large-area oxygen separation device of the present invention to be operated at 225 Celcius with perfluorinated polymer interlayers. Such temperatures would typically result in 10⁻⁴ to 10⁻⁵ the magnitude of oxygen permeation 30 normally useful in solid-oxide fuel cells and solid-oxide oxygen generating systems. However, this drop in oxygen permeation may be compensated by a corresponding increase in the electrode area of the functioning device, since formation of the disclosed electrolytic structures may be economically performed over large flexible substrates; namely, the aforementioned Kapton film.

Although the present invention has been described in detail with reference to the embodiments shown in the drawing, it is not intended that the invention be restricted to such embodiments. It will be apparent to one practiced in the art that various departures from the foregoing description and drawing may be made without departure from the scope or spirit of the invention. The above description of illustrated embodiments of the invention is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description. Furthermore, the particular features, structures, or characteristics may be combined in any suitable manner in one or more embodiments.

### NUMBERED ELEMENTS IN FIGURES

protected article (1)
electrolytic layer (2)
anode layer (3)
cathode layer (4)
catalytic layer (5)
intermediate polymer layer (6)
electrolytic assembly (7)
top insulating layer (8)
power source (9)
electrical circuit (10)
separation layer (11)
electrolytic stack (14)
passive barrier (15)
polymer layer (16)
inorganic layer (17)
first polymer layer (18)
inter-electrolyte layer (21)
inorganic phase (22)
organic phase (23)
heterogeneous layer (24)
flexible substrate (25)

What is claimed is:

1. An electrolytic assembly for oxygen separation, characterized by:
a) a first layer comprising an organic material;
b) an electrolytic layer including an oxygen-conducting material formed adjacent to the first layer, so that the electrolytic layer provides a conductivity for oxygen ions; and,
c) electric field-producing means, the field-producing means disposed to provide an electric field within the electrolytic layer so that oxygen ions are transported through the electrolytic layer when the electric field is provided.

2. The electrolytic assembly of claim 1, wherein the electrolytic layer comprises a heterogeneous material.

3. The electrolytic assembly of claim 1, wherein the assembly is repeated to form a multilayer barrier structure.

4. The electrolytic assembly of claim 1, wherein the assembly is utilized in equipment for production of pure oxygen.

5. The electrolytic assembly of claim 1, wherein the assembly is utilized in equipment for production of electrical power.

6. A method for forming an oxygen separation device, comprising the steps:
a) providing a flexible substrate comprising an organic material;
b) forming a first electrically-conducting layer over the substrate;
c) forming an ion-conducting layer over the first layer; the ion-conducting layer providing a conductivity for oxygen ions, and
d) forming a second electrically-conducting layer adjacent to the ion-conducting layer opposite the first electrically-conducting layer, so that oxygen ions are transported through the ion-conducting layer when an electric field is formed between the first electrically-conductive layer and second electrically-conductive layer.

7. The method of claim 4, wherein the method is used in the manufacture of flexible displays.

8. The method of claim 4, wherein the substrate is a thin flexible polymer.

9. An organic semiconductor device, characterized by:
a) a first material layer, the first layer including an organic semiconductor;
b) an ion-conducting layer formed adjacent the first layer, the electrolytic layer including an oxygen-conducting material, so that the electrolytic layer possesses a conductivity to oxygen ions;
c) electric field means, the electric field means comprising at least an electrically conductive layer adjacent the electrolytic layer for providing an electric field within the electrolytic layer, so that oxygen ions are conducted away from the semiconductor when the field is provided.

10. The organic semiconductor device of claim 7, wherein the device is an organic light-emitting diode.

11. The organic semiconductor device of claim 7, wherein the device is an organic switching device.

12. The organic semiconductor device of claim 7, wherein the ion-conducting layer is part of a multilayer barrier.

13. The organic semiconductor device of claim 7, wherein the ion-conducting layer is used in conjunction with a passive multilayer barrier

14. The organic semiconductor device of claim 7, wherein the first layer is a flexible material.

15. The organic semiconductor device of claim 7, wherein the device is a flexible display device.

16. The organic semiconductor device of claim 7, wherein additional layers are formed between the first layer and the ion-conducting layer.
